(19) United States
(12) Patent Application Publication
(10) Pub. No.: US 2009/0178276 A1
(43) Pub. Date: Jul. 16, 2009

(54) METHOD FOR FORMING CIRCUIT IN MAKING PRINTED CIRCUIT BOARD

(75) Inventors: YUNG-WEI LAI, Tayuan (TW); FENG-YAN HUANG, Shenzhen City (CN); SHING-TZA LIOU, Tayuan (TW)

Correspondence Address: PCE INDUSTRY, INC.;ATT. Steven Reiss, 458 E. LAMBERT ROAD, FULLERTON, CA, 92835, US

(73) Assignees: FUKUI PRECISION COMPONENT (SHENZHEN) CO., LTD., Shenzhen City (CN); FOXCONN ADVANCED TECHNOLOGY INC., Tayuan (TW)

(21) Appl. No.: 12/184,942

(22) Filed: Aug. 1, 2008

(30) Foreign Application Priority Data
Jan. 16, 2008 (CN) 200810300121.2

(51) Int. Cl. H05K 3/02

(52) U.S. Cl. 29/846

(57) ABSTRACT

A method for forming circuit in making a printed circuit board includes the following steps. A patterned photoresist layer is formed on a surface of an insulating substrate such that a first portion of the surface of the insulating substrate is exposed and a second portion of the surface of the insulating substrate is covered by the patterned photoresist layer. An electrically conductive layer is deposited on the first portion of the surface of the insulating substrate so as to obtain a circuit formed on the surface of the insulating substrate. The patterned photoresist layer is removed from the surface second portion of the surface of the insulating substrate.

### BACKGROUND

1. Field of the Invention

The present invention relates to methods for forming printed circuit boards (PCBs) and, particularly, to a method for forming circuits in making a printed circuit board.

2. Description of Related Art

Nowadays, printed circuit boards are widely used in electronic products for electrical connection. In order to achieve miniaturization and multifunction of electronic products, printed circuit boards have become smaller and smaller and have high density interconnection.

Generally, circuits of printed circuit boards are manufactured using a photo-lithographic process. The photo-lithographic process includes a series of processes, such as, coating photoresist layer on a copper clad laminate, exposing the photoresist layer to light beam, developing the photoresist layer to obtain a photoresist pattern, etching the copper clad laminate to obtain a circuit pattern corresponding to the photoresist pattern, peeling off the photoresist pattern, and other required steps. Clearly, the photo-lithographic process is complicated, needs a lot of chemical materials and creates a great deal of non-disposable waste. Therefore, the photo-lithographic process complicates the process of manufacturing the printed circuit boards and cause pollution to the environment. In addition, a thickness of the circuit pattern made using the photo-lithographic process is no less than 10 micrometers. Therefore, the photo-lithographic process limits high density and miniaturization of the printed circuit boards.

What is needed, therefore, is a method for forming circuits in making a printed circuit board which can overcome the above-described problems.

### SUMMARY

An exemplary embodiment of a method for forming circuit in making a printed circuit board includes the following steps. A patterned photoresist layer is formed on a surface of an insulating substrate such that a first portion of the surface of the insulating substrate is exposed and a second portion of the surface of the insulating substrate is covered by the patterned photoresist layer. An electrically conductive layer is deposited on the first portion of the surface of the insulating substrate so as to obtain a circuit formed on the surface of the insulating substrate. The patterned photoresist layer is removed from the surface second portion of the surface of the insulating substrate.

Advantages and novel features will become more apparent from the following detailed description when taken in conjunction with the accompanying drawings.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a flowchart of a method for forming a circuit in making a printed circuit board, according to a first embodiment.

FIG. 2 is a cross-sectional view of an insulating substrate for forming a circuit using the method described in FIG. 1.

FIG. 3 is a cross-sectional view of a patterned photoresist layer formed on the insulating substrate of FIG. 2.

FIG. 4 is a cross-sectional view of a seed layer formed on the patterned photoresist layer of FIG. 3.

FIG. 5 is a cross-sectional view of an electrically conductive layer formed on the seed layer of FIG. 4.

FIG. 6 is a cross-sectional view of the circuit after peeling off the patterned photoresist layer.

### DETAILED DESCRIPTION

An embodiment will now be described in detail below with reference to the drawings.

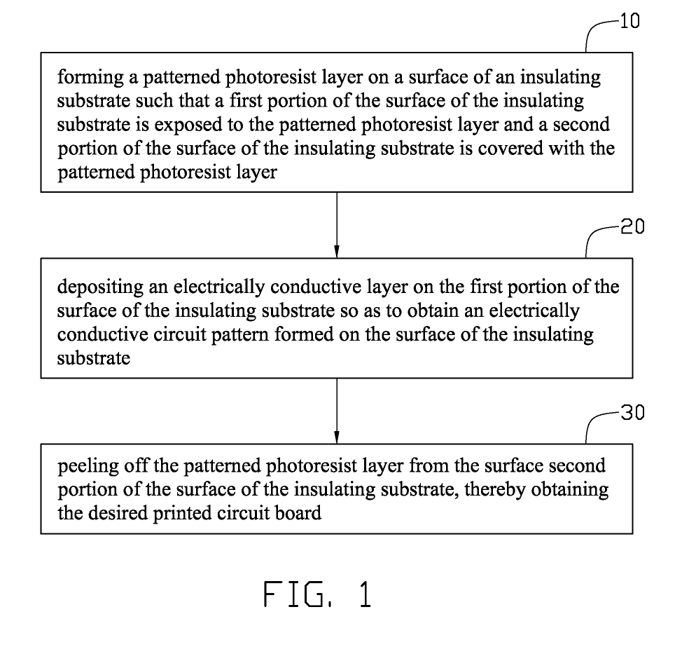

Referring to FIG. 1, a method for forming a circuit in making a printed circuit board includes the following steps. In a general step 10, a patterned photoresist layer is formed on a surface of an insulating substrate such that a first portion of the surface of the insulating substrate is exposed to the patterned photoresist layer and a second portion of the surface of the insulating substrate is covered with the patterned photoresist layer. In a general step 20, an electrically conductive layer is deposited on the first portion of the surface of the insulating substrate, thereby an electrically conductive circuit being formed on the surface of the insulating substrate. In a general step 30, the patterned photoresist layer is peeled off from the second portion of the surface of the insulating substrate, thereby obtaining the desired circuit.

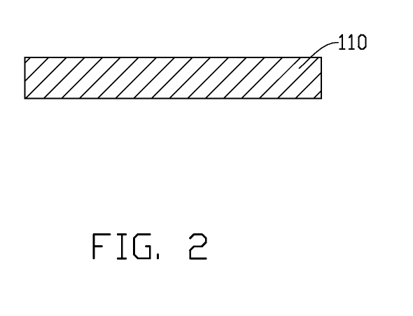

The circuit can be formed in making a flexible printed circuit board, a rigid printed circuit board, or a rigid-flexible printed circuit board. In the present illustrated embodiment, the circuit pattern is formed in making a flexible printed circuit board. The method described in FIG. 1 is embodied in the following with reference to FIG. 2 to FIG. 6.

In a general first step, as shown in FIG. 2, an insulating substrate 110 is provided. The insulating substrate 110 is made of suitable flexible material, such as polyimide (PI), polyethylene terephthalate (PET), polyarylene ether nitrile (PEN), etc.

A structure of the insulating substrate 110 is designed according to a desired configuration of a printed circuit board 100 to be manufactured. For example, assuming a single-layer printed circuit board is to be manufactured, the insulating substrate 110 is an insulating layer. If a multi-layer printed circuit board is to be manufactured, the insulating substrate 110 can be either an insulating layer, or a combination of an insulating layer and a single-layer printed circuit board.

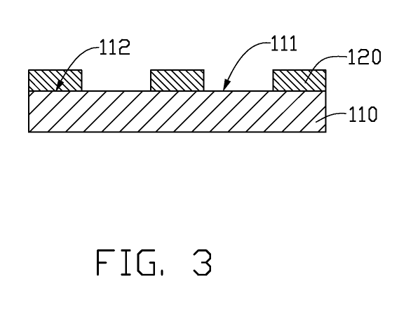

In a second general step, as shown in FIG. 3, a patterned photoresist layer 120 is formed on at least a surface of the insulating substrate 110. In the present embodiment, the patterned photoresist layer 120 is formed on one surface of the insulating substrate 110. A detailed process for forming the photoresist layer 120 includes the following steps. Firstly, a photoresist layer 121 is formed on the surface of the insulating substrate 110. Secondly, the photoresist layer 121 is exposed to light beams and is developed using a developer. As a result, the photoresist layer 121 is transformed into the desired patterned photoresist layer 120. Because the insulating substrate 110 is overlaid by the patterned photoresist layer 120, the surface of the insulating substrate 110 includes a first portion 111 exposed to the patterned photoresist layer 120 and a second portion 112 overlaid by the patterned photoresist layer 120.

The photoresist layer 121 can be a dry photoresist or a liquid photoresist. The dry photoresist is formed on the surface of the insulating substrate 110 using a laminating method. The liquid photoresist is formed on the surface of the insulating substrate 110 using a spin-coating method or a screen printing method. The photoresist layer 121 is comprised of an organic resin, e.g., an acrylic resin. In the present embodiment, the photoresist layer 121 is a dry film of the acrylic resin.

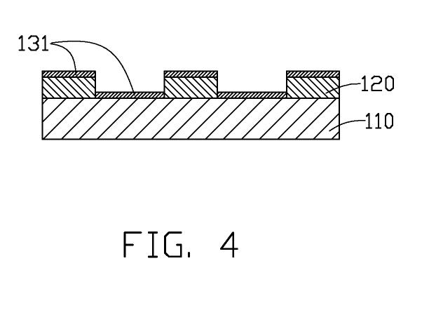

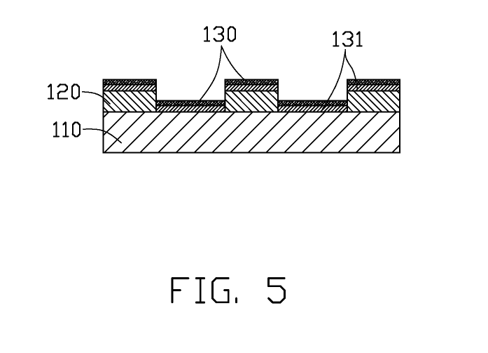

In a general third step, as shown in FIG. 4 and FIG. 5, an electrically conductive metal layer 130 is formed on the first portion 111 of the surface of the insulating substrate 110 using a depositing method, as a result, a patterned electrically conductive metal layer 130, i.e., a patterned trace, is obtained. The electrically conductive metal layer 130 is made of copper, silver, aluminum, any alloy thereof. In the present embodiment, the electrically conductive metal layer 130 is made of copper.

In order to ensure the electrically conductive metal layer 130 is firmly combined with the first portion 111 of the surface of the insulating substrate 110, a seed layer 131 is predisposed on the first portion 111 as shown in FIG. 4. The seed layer 131 can be a nickel layer, a silver layer, or a palladium layer. The depositing method can be a chemical vapor depositing method or a physical vapor depositing method. In the present embodiment, the seed layer 131 is a nickel layer and is formed on the first portion 111 using a heat vaporization method. After the seed layer 131 is formed on the first portion 111, the electrically conductive metal layer 130 is then formed on the seed layer 131 using the heat vaporization method.

In a process to heat vaporize the seed layer 131 on the insulating substrate 110, the whole structure of the insulating substrate 110 having the patterned photoresist layer 120 is disposed in a vacuum chamber to perform the heat vaporization process. The seed layer 131 is formed on both of the first portion 111 of the insulating substrate 110 and a surface of the patterned photoresist layer 120, as shown in FIG. 4. Similarly, in the process of forming the electrically conductive metal layer 130 on the seed layer 131, the electrically conductive metal layer 130 is heat vaporized and deposited on the entire surface of the seed layer 131 formed on the first portion 111 and the patterned photoresist layer 120, as shown in FIG. 5.

Alternatively, in the process to heat vaporize the seed layer 131 on the insulating substrate 110, the surface of the patterned photoresist layer 120 is covered with a mask in such a manner that the seed layer 131 is only deposited on the first portion 111 of the surface of the insulating substrate 110. Similarly, in the process to form the electrically conductive metal layer 130 on the seed layer 131, the surface of the patterned photoresist layer 120 is also covered with the mask in such a manner that the electrically conductive metal layer 130 is only deposited on the surface of the seed layer 131.

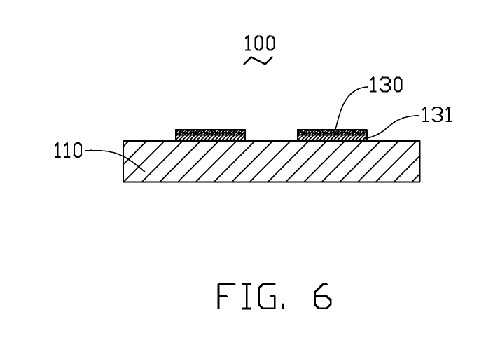

Finally, the patterned photoresist layer 120 having the seed layer 131 and the electrically conductive metal layer 130 formed thereon is peeled off using a remover. Specifically, the whole configuration shown in FIG. 5 is immerged in a remover, e.g., sodium hydroxide, to dissolve the patterned photoresist layer 120, thus the patterned photoresist layer 120 together with the seed layer 131 and the electrically conductive metal layer 130 formed thereon are peeled off from the insulating substrate 110, thereby a desired printed circuit board 100 is obtained, as shown in FIG. 6. Referring to FIG. 6, the finally obtained printed circuit board 100 includes the insulating substrate 110, a patterned seed layer 131 formed on the insulating substrate 110, and the patterned electrically conductive metal layer 130 is formed on the patterned seed layer 131.

With respect to the conventional photo-lithographic process of making the patterned circuit layer of the printed circuit boards, due to complex processes and low precision of the process parameters, a thickness of patterned circuit layer of the printed circuit boards made by such photo-lithographic process is limited to be no less than 10 micrometers. Therefore, the conventional photo-lithographic process disadvantages the miniaturization and concentration of the circuits of the printed circuit boards. However, in the present embodiment, because the electrically conductive metal layer 130 is made using the deposition method, a thickness of the electrically conductive metal layer 130 can be equal to or less than 8 micrometers, preferably equal to or less than 1 micrometer. In the present illustrated embodiment, the thickness of the electrically conductive metal layer 130 is in a range from about 0.1 micrometers to about 0.15 micrometers. Therefore, the patterned electrically conductive metal layer 130 (i.e., the patterned circuits) made by the deposition method facilitates the miniaturization and concentration of the circuits of the printed circuit boards.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A method for forming a circuit in making a printed circuit board, the method comprising:
forming a patterned photoresist layer on a surface of an insulating substrate such that a first portion of the surface of the insulating substrate is exposed and a second portion of the surface of the insulating substrate is covered by the patterned photoresist layer;
depositing an electrically conductive layer on the first portion of the surface of the insulating substrate so as to obtain a circuit formed on the surface of the insulating substrate; and
removing the patterned photoresist layer from the second portion of the surface of the insulating substrate.

2. The method as claimed in claim 1, wherein the electrically conductive layer is deposited on the first portion of the surface of the insulating substrate using a physical vapor deposition method or a chemical vapor deposition method.

3. The method as claimed in claim 1, wherein prior to the step of depositing the electrically conductive layer, a seed layer is deposited on the first portion of the surface of the insulating substrate.

4. The method as claimed in claim 3, wherein during the step of depositing the seed layer, the seed layer is only deposited on the first portion of the surface of the insulating substrate.

5. The method as claimed in claim 3, wherein the seed layer is one of a nickel layer, a silver layer and a palladium layer.

6. The method as claimed in claim 5, wherein the electrically conductive layer is comprised of copper, silver, aluminum, or any alloy thereof.

7. A method for forming a circuit in making a printed circuit board, the method comprising:
forming a patterned photoresist layer on a surface of an insulating substrate such that a first portion of the surface of the insulating substrate is exposed and a second portion of the surface of the insulating substrate is covered by the patterned photoresist layer;
placing the insulating substrate having the patterned photoresist layer formed thereon in a vacuum environment, and exposing the first portion of the surface of the insulating substrate and a surface of the patterned photoresist layer to the vacuum environment;
depositing an electrically conductive layer on the first portion of the surface of the insulating substrate and the surface of the patterned photoresist layer; and
removing the patterned photoresist layer from the surface second portion of the surface of the insulating substrate, thereby obtaining a circuit formed on the first portion of the surface of the insulating substrate.

8. The method as claimed in claim 7, wherein the electrically conductive layer is deposited on the first portion of the surface of the insulating substrate and the surface of the patterned photoresist layer using physical vapor deposition method or a chemical vapor deposition method.

9. The method as claimed in claim 7, wherein prior to the step of depositing the electrically conductive layer, a seed layer is deposited on the first portion of the surface of the insulating substrate and the surface of the patterned photoresist layer.
